(19) United States
(12) Patent Application Publication
(10) Pub. No.: US 2023/0028219 A1
(43) Pub. Date: Jan. 26, 2023

(54) DIE BONDING METHOD AND DIE BONDING APPARATUS

(71) Applicant: SEMES CO., LTD., Cheonan-si (KR)

(72) Inventor: Chang Jin KIM, Suwon-si (KR)

(73) Assignee: SEMES CO., LTD., Cheonan-si (KR)

(21) Appl. No.: 17/864,978

(22) Filed: Jul. 14, 2022

(30) Foreign Application Priority Data
Jul. 21, 2021 (KR) 10-2021-0095520

(51) Int. Cl. H01L 23/00; H01L 25/065

(52) U.S. Cl. CPC H01L 24/80; H01L 24/74; H01L 25/0657; H01L 2924/012; H01L 2224/80132; H01L 2224/80894; H01L 2224/80908; H01L 24/08; H01L 2224/08145; H01L 2224/08225; H01L 2225/06524

(57) ABSTRACT

A die bonding method includes obtaining information about a quality grade of each die of a plurality of dies placed at a wafer, picking up a first die among the plurality of dies from the wafer, identifying a bonding location of a plurality of bonding locations from a substrate according to a quality grade of the first die, and bonding the first die to the bonding location of the substrate.

### CROSS REFERENCE TO RELATED APPLICATION

The present application claims priority to Korean Patent Application No. 10-2021-0095520, filed Jul. 21, 2021, the entire contents of which is incorporated by reference herein for all purposes.

### BACKGROUND OF THE INVENTION

### Field of the Invention

The present disclosure relates to a die bonding method and a die bonding apparatus and, more particularly, to a die bonding method and a die bonding apparatus for bonding a die on a substrate taking into account the quality grade of the die.

### Description of the Related Art

A semiconductor manufacturing process is a process to fabricate semiconductor devices on a wafer, and includes, for example, exposure, dislocation, etching, ion implantation, and cleaning. A process for bonding each die to a substrate (e.g., a printed circuit board (PCB)) for packaging may be performed with respect to a die configured in a chip unit through a semiconductor manufacturing process.

After dies are bonded to the substrate, individual chips are produced through cutting and sorting processes, and recently, a process of manufacturing chips by stacking a plurality of dies has been introduced.

### SUMMARY OF THE INVENTION

Accordingly, the present disclosure has been made keeping in mind the above problems occurring in the related art, and the present disclosure is intended to provide a die bonding method and a die bonding apparatus for ensuring a consistent chip quality through a bonding process that considers the quality of each die.

The objectives of the present disclosure are not limited to those mentioned above, and other objectives not mentioned will be clearly understood by those skilled in the art from the following description.

According an embodiment of the present disclosure, a die bonding method includes obtaining information about a quality grade of each die of a plurality of dies placed at a wafer, picking up a first die among the plurality of dies from the wafer, identifying a bonding location of a plurality of bonding locations from a substrate according to a quality grade of the first die, and bonding the first die to the bonding location of the substrate.

According to an embodiment of the present disclosure, a die bonding apparatus includes a die stage on which a wafer having a plurality of dies is seated and the plurality of dies are inspected, a die pick-up handler picking up a first die among the plurality of dies from the die stage, and bonding the first die to a substrate, and a controller that controls the die pick-up handler to obtain information on a quality grade of each die of the plurality of dies, to pick up the first die from the wafer, to identify a bonding location among a plurality of bonding locations of the substrate according to a quality grade of the first die picked up from the wafer, and to bond the first die to the bonding location.

According to an embodiment of the present invention, a die bonding apparatus includes a wafer stage supporting a wafer containing a plurality of dies, a die ejector that selectively separates a first die of the plurality of dies from the wafer stage, a die stage on which the first die separated from the wafer is seated and inspected, a die pick-up handler that picks up the first die from the die stage and bonds the first die to a substrate, a bonding stage that supports the substrate, and a controller that controls the die pick-up handler to obtain information on a quality grade of each die of the plurality of dies, to pick up the first die from the wafer, to identify a bonding location among a plurality of bonding locations of the substrate according to a quality grade of the first die picked up from the wafer, and to bond the first die to the bonding location of the substrate.

According to the present disclosure, by bonding the die to the bonding location corresponding to the grade of the die, the dies having the same grade are bonded to the same corresponding location, thereby ensuring a consistent chip quality.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 to 3 show a schematic structure of a die bonding apparatus to which the present disclosure may be applied;

FIG. 4 shows an example of a map indicating the grade of dies located on a wafer;

FIGS. 5 and 6 show a case in which sequential bonding is applied;

FIG. 7 is a flowchart for a die bonding method according to the present disclosure;

FIGS. 8 and 9 show a case in which bonding by grade according to an embodiment of the present disclosure is applied; and

FIGS. 10 to 12 show examples of graded bonding locations of dies on a substrate.

### DETAILED DESCRIPTION OF THE INVENTION

Hereinafter, with reference to the accompanying drawings, embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are given to the same or similar elements throughout the specification.

In addition, in various embodiments, components having the same configuration will be described only in the representative embodiment using the same reference numerals, and only configurations different from the representative embodiment will be described in other embodiments.

Throughout the specification, when a part is said to be “connected (or coupled)” with another part, this includes not only the case of “directly connected (or coupled)” but also the case of “indirectly connected (or coupled)” with another member therebetween. In addition, when a part “includes” a certain component, it means that other components may be further included, rather than excluding other components, unless otherwise stated.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having a meaning consistent with the meaning in the context of the related art, unless explicitly defined in this application, it should not be construed in an ideal or overly formal sense.

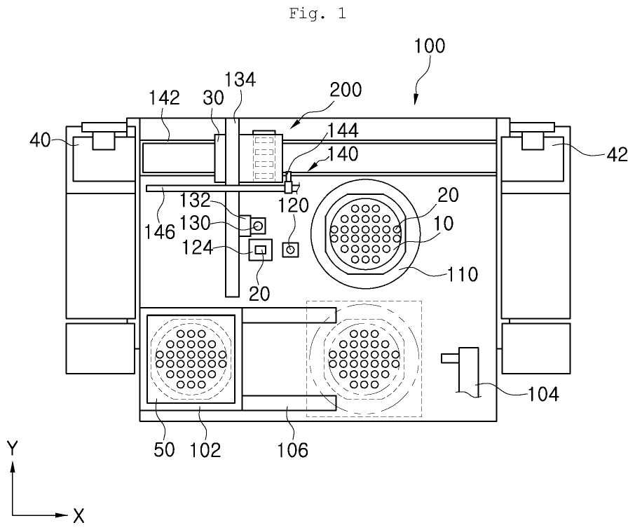

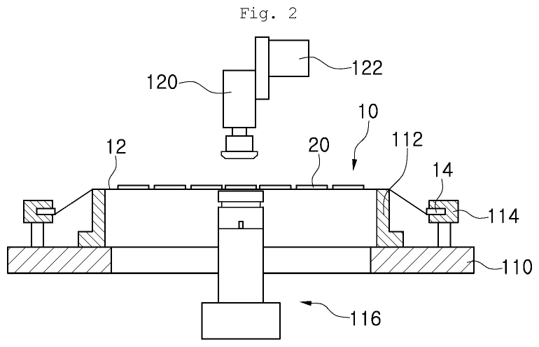

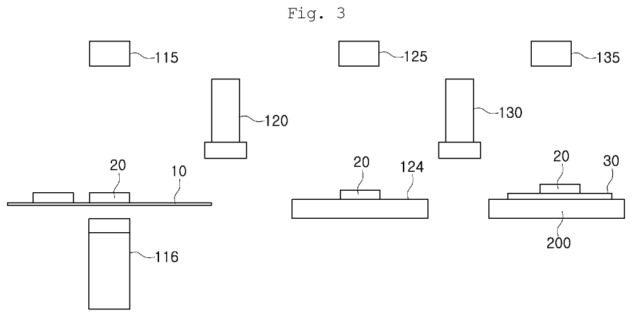

FIGS. 1 to 3 show a schematic structure of a die bonding apparatus to which the present disclosure may be applied. FIG. 1 shows the structure of bonding equipment 100, FIG. 2 shows the schematic structure of a die ejecting unit, and FIG. 3 shows a process of bonding a die 20 to a substrate 30 after separating the die 20 from the wafer 10.

The bonding equipment 100 may be used to bond the die 20 onto the substrate 30 (e.g., a printed circuit board (PCB), a lead frame) in a die bonding process for manufacturing a semiconductor package.

An apparatus according to an embodiment of the present disclosure includes: a wafer stage 110 that supports a wafer 10 including individualized dies 20 and selectively separates the dies 20; a die ejecting unit (i.e., a die ejector) 116 that selectively separates the die 20 from the wafer stage 110; a die transfer unit 120 that transfers the die 20 from the wafer stage 110; a die stage 124 on which the die 20 transferred by the die transfer unit 120 is seated and inspection of the die 20 is performed; a bonding unit (i.e., a die pick-up handler) 130 that picks up the die 20 from the die stage 124 and bonds the die 20 on the substrate 30; and a bonding stage 200 that supports the substrate 30 and transfers the substrate 30 on which bonding is completed to magazines 40 and 42.

The bonding equipment 100 may pick up the die 20 from the wafer 10 including the dies 20 individualized by a dicing process and bond the die 20 onto the substrate 30. The wafer 10 may be provided in a state attached to a dicing tape 12, and the dicing tape 12 may be mounted on a mount frame 14 having a substantially circular ring shape. A cassette 50 in which a plurality of wafers 10 are accommodated is inserted in a load port 102. A wafer transfer unit 104 takes out the wafer 10 from the cassette 50 and loads the wafer 10 on the wafer stage 110, and the wafer transfer unit 104 may move along a guide rail 106 installed between the cassette 50 and the wafer stage 110.

As shown in FIG. 2, an expansion ring 112 in the form of a circular ring may be disposed on the wafer stage 110, and the expansion ring 112 may support an edge portion of the dicing tape. In addition, clamps 114 for holding the mount frame 14, and a clamp drive part (not shown) that expands the dicing tape 12 by lowering the clamps 114 while the dicing tape 12 is supported by the expansion ring 112 may be disposed on the wafer stage 110.

Although not shown, the wafer stage 110 may be configured to be movable in the horizontal direction by a stage drive part (not shown), and the stage drive part may move the wafer stage 110 to a wafer load/unload area (area indicated by a dotted line in FIG. 1) adjacent to an end of the guide rail 106 for loading and unloading the wafer 10. Also, the stage drive part may move the wafer stage 110 to selectively pick up the die 20. That is, the stage drive part may adjust the position of the wafer stage 110 so that the die 20 to be picked up among the dies 20 is located on the top of the die ejecting unit 116.

Referring to FIG. 3, the die 20 separated by the die ejecting unit 116 may be picked up by the die transfer unit 120 disposed above the wafer stage 110. The die transfer unit 120 may pick up the die 20 and then transfer the die 20 onto the die stage 124 disposed on one side of the wafer stage 110, and the bonding unit 130 may pick up the die 20 on the die stage 124 and bond the picked-up die 20 to the substrate 30. Meanwhile, a first vision unit 115 for identifying the location of each die 20 on the wafer 10 is disposed on the wafer stage 110, a second vision unit 125 for inspecting the state of the die 20 is disposed on the die stage 124, and a third vision unit 135 for confirming a bonding location may be disposed on the bonding stage 200.

The substrate 30 may be drawn out from the first magazine 40 and transferred onto the bonding stage 200, and after the bonding process is completed, the substrate 30 may be transferred to and accommodated in the second magazine 42. The bonding equipment 100 may include a substrate transfer unit 140 for transferring the substrate 30 onto the bonding stage 200. For example, the substrate transfer unit 140 may include: the first magazine 40; the bonding stage 200; a gripper 144 for gripping one end of the substrate 30; and a gripper drive unit 146 for moving the gripper 144 in the horizontal direction (X-axis direction). The gripper drive unit 146 may load the substrate 30 onto the bonding stage 200 by moving the gripper 144 after one end of the substrate 30 is gripped by the gripper 144. Although not shown, the substrate transfer unit 140 may further include a second gripper (not shown) for moving the substrate 30 to the second magazine 42 after the bonding process is completed.

The bonding equipment 100 may include: a first head drive unit 132 for picking up the die 20 on the die stage 124 and moving the bonding unit 130 in the vertical direction to bond the die onto the substrate 30; and a second head drive unit 134 for moving the bonding unit 130 in a second horizontal direction (e.g., Y-axis direction) perpendicular to the horizontal direction between the die stage 124 and the bonding stage 200. Although not shown in detail, the bonding unit 130 may include a bonding tool for picking up the die 20 using vacuum pressure, and a heater for heating the die 20. That is, the bonding unit 130 may pick up the die 20 on the die stage 124 and bond the die to the substrate 30. Also, the bonding unit 130 may pick up the die 20 from the wafer 10 and directly bond the die 20 onto the substrate 30.

Meanwhile, on the upper side of the bonding stage 200, a camera may be disposed to image a fiducial mark on the substrate 30 and an area to which the die 20 is to be bonded for adjusting position, that is, for aligning, of the substrate 30.

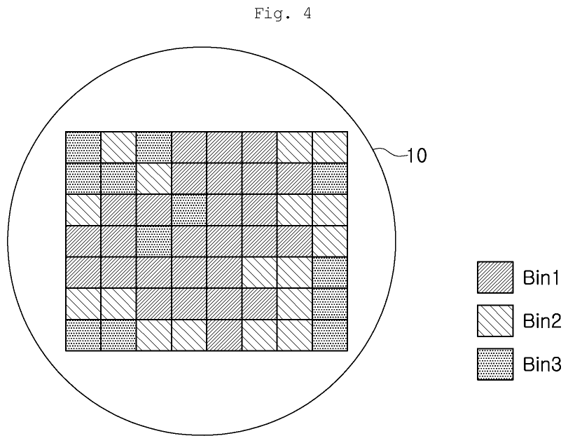

FIG. 4 shows an example of a map indicating the grade of dies located on a wafer. Referring to FIG. 4, a circuit is formed for each area of each die 20 through a processing process for the wafer 10, a grade for each die 20 is determined by an electrical die sorting (EDS) process for each die 20. For example, the grade of the die 20 may be divided into three, and may be named as Bin1, Bin2, and Bin3 in the order of having high quality.

The grade of each die 20 located on the wafer 10 may be stored in the upper control server in the form of a map as shown in FIG. 4, and may be used as necessary. For example, when it is set that the dies 20 with the Bin3 grade are discarded and the dies 20 corresponding to the Bin1 and Bin2 grades are bonded, only the dies 20 corresponding to Bin1 and Bin2 may be set to pick up.

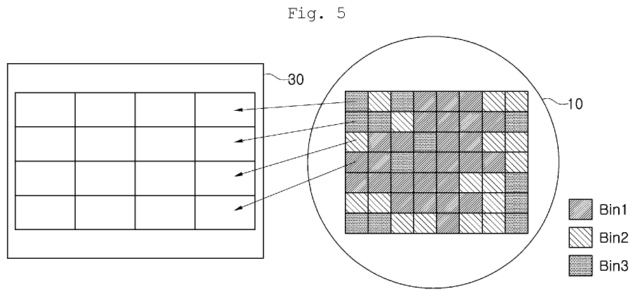

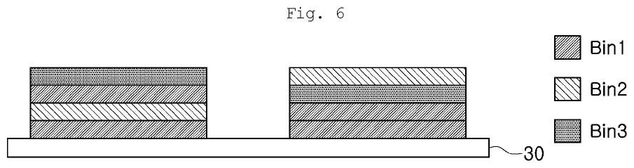

FIGS. 5 and 6 show a case in which sequential bonding is applied. When sequential bonding is applied, the die 20 may be bonded to the substrate 30 after the die 20 is sequentially bonded as the die transfer unit 120 moves along the row or column direction on the wafer 10.

Referring to FIG. 5, in the case of bonding after picking up the die 20 by moving from the upper left location in the column direction, bonding is performed in the order of the die 20 picked up first on the substrate 30 regardless of the grade of the die 20. For example, as shown in FIG. 5, the first picked-up die 20 may be sequentially bonded in the downward direction from the upper-right location of the substrate 30. When bonding is performed in such a sequential manner, the grades of the dies 20 bonded on the substrate 30 are likely to be randomly arranged.

Meanwhile, a plurality of dies 20 may be laminated on a unit partitioned on the substrate 30 and bonded to the substrate 30, and in this case, the dies 20 may be bonded and laminated as shown in FIG. 6. At this time, the dies 20 disposed in the same unit as shown in FIG. 6 are highly likely to have different grades from each other, and as a result, the chip performance of the unit is also likely to be non-uniform.

Accordingly, the embodiment of the present disclosure provides a method of setting the grade of the die 20 to be bonded for each area on the substrate 30 and bonding the die 20 at bonding locations divided by grade. Thus, by classifying the dies 20 bonded on the substrate 30 according to their location, it is possible to more easily manage the quality of the chip. In addition, when a chip is manufactured by stacking a plurality of dies 20, the quality of each chip may be managed to be consistent since one chip is composed of dies 20 of the same grade.

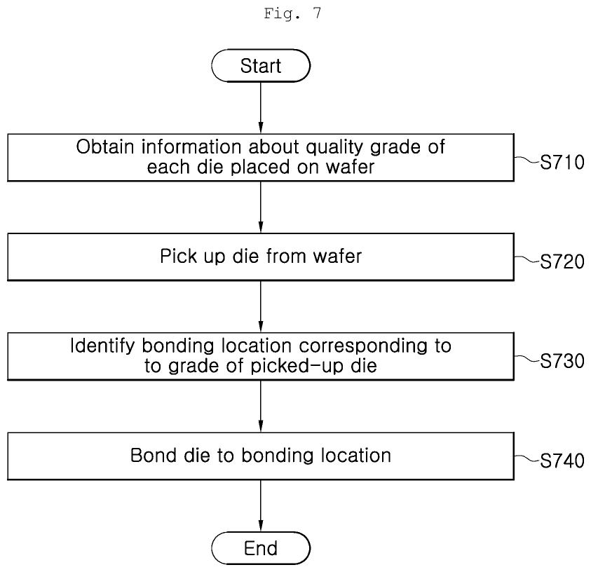

FIG. 7 is a flowchart for a die bonding method according to the present disclosure. A die bonding method according to the present disclosure includes: obtaining (S710) information about a quality grade of each die placed on a wafer; picking up (S720) a die from the wafer; identifying (S730) a bonding location corresponding to the grade of the picked-up die on a substrate; and bonding (S740) the die to the bonding location.

According to the present disclosure, the substrate 30 may be a PCB divided into a plurality of rows and columns.

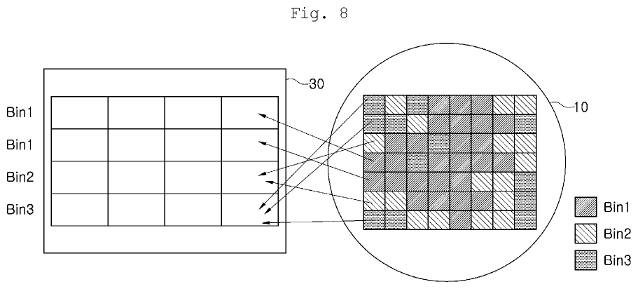

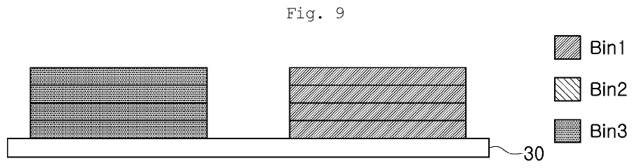

FIGS. 8 and 9 show a case in which bonding by grade according to an embodiment of the present disclosure is applied. Referring to FIG. 8, the first and second columns of the substrate 30 may be set such that the Bin1 grade dies 20 are bonded, the third column of substrate 30 may be set such that the Bin2 grade dies 20 are bonded, and the fourth column of the substrate 30 may be set such that the Bin3 grade dies 20 (i.e., the dies 20 having the Bin3 grade) are bonded.

According to the present disclosure, a plurality of dies 20 may be stacked and bonded on the substrate 30. That is, the step of bonding S740 the die 20 may include bonding the die 20 at a location where the die 20 of the same grade is bonded. When a plurality of dies 20 are stacked and bonded, a chip may be manufactured with the dies 20 of the same grade as shown in FIG. 9 since the dies 20 of the same grade are bonded at the same location. In this case, since one chip is composed of dies 20 of the same grade, uniform quality may be maintained.

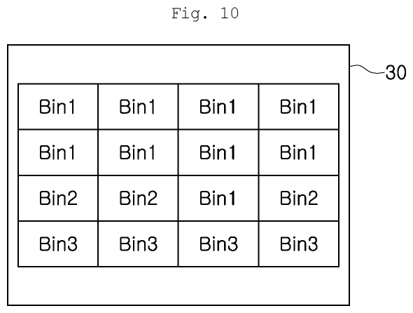

According to an embodiment of the present disclosure, in the substrate 30, the grade of the die 20 to be bonded may be set for each row or each column. As shown if FIG. 10, the grade of the die 20 to be bonded may be set for each column of the substrate 30. For example, the first and second columns may be set such that the Bin1 grade dies 20 (i.e., the dies 20 having the Bin1 grade) are bonded, the third column may be set such that the Bin2 grade dies 20 are bonded, and the fourth column may be set such that the Bin3 grade dies 20 are bonded.

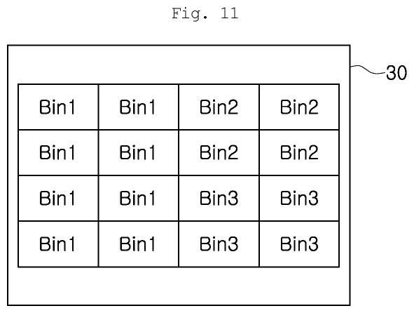

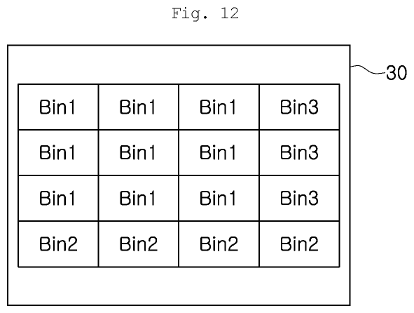

According to another embodiment of the present disclosure, a grade of a die to be bonded may be set for each bonding area composed of one or more rows and columns in the substrate 30. For example, as shown in FIG. 11, the left 4×2 area (the area located in the left two (2) columns and four (4) rows) may be set to bond the Bin1 grade die 20, the right 2×2 area may be set to bond the Bin2 grade die 20 (i.e., the die 20 having the Bin2 grade), and the lower right 2×2 area may be set to bond the Bin3 grade die 20. In addition, the bonding area of the die 20 according to the grade on the substrate 30 may be set as shown in FIG. 12.

According to another embodiment of the present disclosure, the bonding area set for each grade in the substrate 30 may be set on the basis of the number of dies for each grade placed on the wafer 10. For example, when the number of dies 20 exists in the order of Bin1 grade, Bin2 grade, and Bin3 grade, the area where the Bin1 grade die 20 is bonded may be set to be the largest (9 units) as shown in FIG. 12, the area where the Bin2 grade die 20 is bonded may be set to be the second largest (4 units), and the area where the Bin3 grade die 20 (i.e., the die 20 having the Bin3 grade) is bonded may be set to be the smallest (3 units).

An embodiment of the present disclosure may provide a die bonding apparatus to which the above-described die bonding method is applied. The die bonding method according to the present disclosure may be performed by a controller (not shown) that controls each module of the bonding equipment 100.

A die bonding apparatus according to an aspect of the present disclosure includes: a die stage 124 on which the die 20 is seated and inspection of the die 20 is performed; a bonding unit 130 that picks up the die 20 from the die stage 124 and bonds the die 20 on the substrate 30; and a controller for controlling the bonding unit 130. The controller may control the bonding unit 130 to obtain grade information on the quality of each die 20 placed on the wafer 10, pick up the die 20 from the wafer 10, identify a bonding location corresponding to the grade of the die 20 picked up from the substrate 30, and bond the die 20 to a bonding location corresponding to the grade of the picked-up die 20 (i.e., the die 20 picked up from the wafer 10).

A die bonding apparatus according to another aspect of the present disclosure includes: a wafer stage 110 that supports a wafer including individualized dies 20 and selectively separates the dies 20; a die ejecting unit 116 that selectively separates the die 20 from the wafer stage 110; a die transfer unit 120 that transfers the die 20 from the wafer stage 110; a die stage 124 on which the die 20 transferred by the die transfer unit 120 is seated and inspection of the die 20 is performed; a bonding unit 130 that picks up the die 20 from the die stage 124 and bonds the die 20 on the substrate 30; a bonding stage 200 that supports the substrate 30 and transfers the substrate 30 on which bonding is completed to magazines 40 and 42;

and a controller for controlling the bonding unit 130. The controller may control the bonding unit 130 to obtain grade information on the quality of each die 20 placed on the wafer 10, pick up the die 20 from the wafer 10, identify a bonding location corresponding to the grade of the die 20 picked up from the substrate 30, and bond the die 20 to a bonding location corresponding to the grade of the picked-up die 20.

The embodiments and the accompanying drawings in this specification only clearly show a part of the technical idea included in the present disclosure, and thus it will be apparent that all modifications and specific embodiments that can be easily inferred by those skilled in the art within the scope of the technical idea included in the specification and drawings of the present disclosure are included in the scope of the present disclosure.

Therefore, the spirit of the present disclosure should not be limited to the described embodiments, and not only the claims to be described later, but also all equivalents or equivalent modifications to the claims should be construed as being included in the scope of the spirit of the present disclosure.

What is claimed is:

1. A die bonding method, comprising:
obtaining information about a quality grade of each die of a plurality of dies placed at a wafer;
picking up a first die among the plurality of dies from the wafer;
identifying a bonding location of a plurality of bonding locations from a substrate according to a quality grade of the first die; and
bonding the first die to the bonding location of the substrate.

2. The die bonding method of claim 1,
wherein the substrate is a printed circuit board (PCB) divided into a plurality of rows and columns.

3. The die bonding method of claim 2,
wherein dies having the same quality grade are set to be bonded on the same row or column in the plurality of bonding locations of the substrate.

4. The die bonding method of claim 2,
wherein dies having the same quality grade are set to be bonded on the same bonding area of a plurality of bonding areas of the substrate, and
wherein each bonding area is composed of one or more rows and columns in the plurality of bonding locations of the substrate.

5. The die bonding method of claim 4,
wherein the quality grade includes a plurality of grades, and
wherein a size of a bonding area, among the plurality of bonding areas of the substrate, set for each grade of the plurality of grades is set on the basis of a number of dies for each grade in the wafer.

6. The die bonding method of claim 1, further comprising:
stacking a second die, among the plurality of dies, on the first die on the substrate; and
bonding the second die to the first die on the substrate.

7. The die bonding method of claim 6,
wherein the first die and the second die have the same quality grade.

8. A die bonding apparatus, comprising:
a die stage on which a wafer having a plurality of dies is seated and the plurality of dies are inspected;
a die pick-up handler configured to:
pick up a first die among the plurality of dies from the die stage, and
bond the first die to a substrate; and
a controller that controls the die pick-up handler to:
obtain information on a quality grade of each die of the plurality of dies,
pick up the first die from the wafer,
identify a bonding location among a plurality of bonding locations of the substrate according to a quality grade of the first die picked up from the wafer, and
bond the first die to the bonding location.

9. The die bonding apparatus of claim 8,
wherein the substrate is a printed circuit board (PCB) divided into a plurality of rows and columns in the plurality of bonding locations of the substrate.

10. The die bonding apparatus of claim 9,
wherein dies having the same quality grade are set to be bonded on a same row or column in the plurality of bonding locations of the substrate.

11. The die bonding apparatus of claim 9,
wherein dies having the same quality grade are set to be bonded on the same bonding area of a plurality of bonding areas of the substrate, and
wherein each bonding area is composed of one or more rows and columns in the plurality of bonding locations of the substrate.

12. The die bonding apparatus of claim 11,
wherein the quality grade includes a plurality of grades, and
wherein a corresponding bonding area, among the plurality of bonding areas of the substrate, set for each grade of the plurality of grades is set on the basis of a number of dies for each grade in the wafer.

13. The die bonding apparatus of claim 8,
wherein the controller controls the die pick-up handler to:
stack a second die, among the plurality of dies, on the first die on the substrate, and
bond the second die to the first die on the substrate.

14. The die bonding apparatus of claim 13,
wherein the first die and the second die have the same quality grade.

15. A die bonding apparatus, comprising:
a wafer stage supporting a wafer containing a plurality of dies;
a die ejector that selectively separates a first die of the plurality of dies from the wafer stage;
a die stage on which the first die separated from the wafer is seated and inspected;
a die pick-up handler that picks up the first die from the die stage and bonds the first die to a substrate;
a bonding stage that supports the substrate; and
a controller that controls the die pick-up handler to:
obtain information on a quality grade of each die of the plurality of dies,
pick up the first die from the wafer,
identify a bonding location among a plurality of bonding locations of the substrate according to a quality grade of the first die picked up from the wafer, and
bond the first die to the bonding location of the substrate.

16. The die bonding apparatus of claim 15,
wherein the substrate is a printed circuit board (PCB) divided into a plurality of rows and columns in the plurality of bonding locations of the substrate.

17. The die bonding apparatus of claim 16,
wherein dies having the same quality grade are set to be bonded on the same row or column in the plurality of bonding locations of the substrate.

18. The die bonding apparatus of claim 16,
wherein dies having the same quality grade are set to be bonded on the same bonding area of a plurality of bonding areas of the substrate, and
wherein each bonding area is composed of one or more rows and columns in the plurality of bonding locations of the substrate.

19. The die bonding apparatus of claim 18,
wherein the quality grade includes a plurality of grades, and
wherein a size of a bonding area, among the plurality of bonding areas of the substrate, set for each grade of the plurality of grades is set on the basis of a number of dies for each grade in the wafer.

20. The die bonding apparatus of claim 15,
wherein the controller controls the die pick-up handler to:
stack a second die, among the plurality of dies, on the first die on the substrate, and
bond the second die to the first die on the substrate.
